(19) United States
(12) Patent Application Publication
(10) Pub. No.: US 2011/0255335 A1
(43) Pub. Date: Oct. 20, 2011

(54) CHARGE TRAP MEMORY HAVING LIMITED CHARGE DIFFUSION

(76) Inventor: Alessandro Grossi, Milano (IT)

(21) Appl. No.: 12/764,063

(22) Filed: Apr. 20, 2010

(51) Int. Cl. G11C 16/00; H01L 29/792; H01L 21/28

(52) U.S. Cl. 365/185.01; 438/591; 257/324; 257/E21.21; 257/E29.309

(57) ABSTRACT

Subject matter disclosed herein relates to flash memory, and more particularly to a charge trap memory and a process flow to form same.

### BACKGROUND

1. Field

Subject matter disclosed herein relates to flash memory, and more particularly to a charge trap memory and a process flow to form same.

2. Information

A flash memory typically preserves stored information even in power-off conditions. In such memories, in order to change a logic state of a cell, e.g. a bit, an electric charge present in a storage layer of the cell may be changed by application of electric potentials to various portions of the cell. A “0” state typically corresponds to a negatively charged storage layer and a “1” state typically corresponds to a positively charged storage layer, for example. As intended, a non-volatile memory may preserve stored information over time, but a reliability of such a memory to preserve such stored information may be limited by, for example, a leakage current or charge diffusion that may be observed at even relatively low electric fields. Such low level charge loss and/or charge gain mechanisms, which may lead to information loss, are undesirable since flash memory devices are expected to be able to store information on the order of at least several years.

### BRIEF DESCRIPTION OF THE FIGURES

Non-limiting and non-exhaustive embodiments will be described with reference to the following figures, wherein like reference numerals refer to like parts throughout the various figures unless otherwise specified.

FIGS. 1-5 are cross-section views of portions of a memory device, according to an embodiment.

FIG. 6 is a cross-section view of a memory array, according to an embodiment.

FIG. 7 is a flow diagram of a process to form a memory device, according to an embodiment.

FIG. 8 is a schematic view of a computing system and a memory device, according to an embodiment.

### DETAILED DESCRIPTION

Reference throughout this specification to “one embodiment” or “an embodiment” means that a particular feature, structure, or characteristic described in connection with the embodiment is included in at least one embodiment of claimed subject matter. Thus, the appearances of the phrase “in one embodiment” or “an embodiment” in various places throughout this specification are not necessarily all referring to the same embodiment. Furthermore, the particular features, structures, or characteristics may be combined in one or more embodiments.

In an embodiment, a memory device may have a particular configuration to provide a benefit such as improved memory retention by reducing a leakage current from one memory cell to an adjacent memory cell. Such a memory device may comprise an array of charge trap memory cells, such as charge trap NAND flash memory cells, for example. Such memory cells may comprise an isolated region (e.g., a shallow trench isolation (STI) region) on a substrate, semiconductor material lines formed on the STI region, an active dielectric stack conformally covering the semiconductor lines, and a conductive layer at least partially covering the active dielectric stack. In one implementation, an active dielectric stack may lead to a modification of electric charge inside a storage layer to modify a logic state of a cell. For example, such an active dielectric stack may comprise a double silicon dioxide layer including a silicon nitride layer to be used as a storage layer. In a particular implementation, an active dielectric stack may comprise an oxide-nitride-oxide (ONO) stack, though claimed subject matter is not so limited.

Semiconductor materials for lines formed on an STI region may comprise poly-crystalline or crystalline silicon, gallium arsenide, and/or germanium, for example. A conductive layer may comprise polysilicon, titanium, titanium nitride, tantalum nitride (TaN), tungsten (W), tungsten nitride (WN), tungsten silicide (WSi2), and/or a combination thereof, just to name a few examples. Of course, such materials are merely examples, and claimed subject matter is not so limited. In such a configuration, at least portions of the conductive layer may extend to substantially below the semiconductor lines. In one implementation, such a configuration may result from over-etching a semiconductor thin film during a patterning process that leads to formation of the above-mentioned semiconductor lines. Here, “over-etching” a multilayer device refers to a process of etching down through a first layer and at least partially into a second layer underlying the first layer. Accordingly, such over-etching may result in deep trenches that extend into the STI region, substantially below the semiconductor lines. An active dielectric stack may extend to substantially below the semiconductor lines. Accordingly, at least partially filling such deep trenches with a conductive layer may then result in at least portions of the overlying conductive layer extending to substantially below the semiconductor lines. Here, “substantially below” a structure and/or a layer refers to a distance below a surface of the structure and/or layer that allows for particular features or benefits of memory devices as described below. In one implementation, an over-etch depth may be greater than an active dielectric thickness and less than a depth for which trenches may not be filled by conductive layer. As explained in detail below, conductive material and/or portions of an active dielectric stack residing below the semiconductor lines may provide a benefit such as improved channel control during operation of memory cells, and/or increased tunnel electric field. Also, conductive material and/or portions of an active dielectric stack residing below the semiconductor lines may result in an increased path length for charge particles diffusing between adjacent memory cells. Thus, such an increased path length may provide a benefit such as improved memory retention by reducing a leakage current from one memory cell to an adjacent memory cell. Of course, benefits of such a memory device are not limited to those described above, and claimed subject matter is also not so limited.

In an embodiment, a process of fabricating a memory device as described above may comprise forming peripheral circuitry and/or a shallow trench isolation (STI) region on a substrate. A first semiconductor layer may then be deposited to at least partially cover the peripheral circuitry and the STI region. Next, over-etching the first semiconductor layer over the STI region may be performed to form trenches to expose and to etch the STI region. For example, such over-etching may comprise etching the STI region at the bottom of the trenches to deepen the trenches to substantially below the first semiconductor layer. In an implementation, a process of fabricating such a memory device may further comprise conformally forming an active dielectric stack on the etched first semiconductor layer and surfaces of the deepened trenches to substantially below the first semiconductor layer. Subsequently, the deepened trenches may be at least partially filled to substantially below the first semiconductor layer with a second conductive layer to form an array of memory cells. Again, as explained in detail below, conductive material and/or portions of an active dielectric stack residing below the semiconductor lines may provide a benefit such as improved channel control during operation of memory cells comprising the cell channels. Also, semiconductor material and/or portions of an active dielectric stack residing below semiconductor lines may allow for an increased path length, providing a benefit such as improved memory retention by reducing a leakage current from one memory cell to an adjacent memory cell. Of course, such a process of fabricating a memory device is merely an example, and claimed subject matter is not so limited.

In an embodiment, a process of fabricating a memory device may further comprise forming a memory array layer on an STI region, wherein the memory device comprises a three-dimensional memory device. In such an embodiment, a three-dimensional memory structure may comprise an interlayer dielectric layer (ILD) to cover peripheral circuitry and two or more levels of memory cell arrays formed on the ILD. Such an ILD may comprise, for example, silicon oxide deposited using various techniques including low pressure chemical vapor deposition (LPCVD), chemical vapor deposition (CVD), and/or atomic layer deposition (ALD). Such peripheral circuitry, for example, may comprise control circuitry to select and/or operate gate lines, bit lines, and/or drain-source lines, for example. Such peripheral circuitry may also comprise sense amplifier circuitry, though claimed subject matter is not so limited. Despite the name, peripheral circuitry need not reside on the periphery of a memory structure. In particular, such peripheral circuitry may be disposed between a substrate upon which the peripheral circuitry is built and two or more levels of memory cell arrays. In one implementation, such a three-dimensional memory structure may comprise a NAND flash memory, though claimed subject matter is not limited in this respect.

In another embodiment, a process flow to fabricate a three-dimensional memory structure may begin by forming peripheral circuitry on a substrate. After covering peripheral circuitry with insulating material and/or an ILD, a first memory array level may be formed using an over-etch technique, as mentioned above. In particular, over-etching a first semiconductor layer into an underlying STI region may form deep trenches that extend into the STI region. Such deep trenches may then be at least partially filled with an active dielectric stack and a conductive layer to below the first semiconductor layer. After covering a first memory array level with further insulating material and/or an ILD, another memory array level may be formed, and so on. Of course, such details of a process to fabricate a three-dimensional memory structure are merely examples, and claimed subject matter is not so limited.

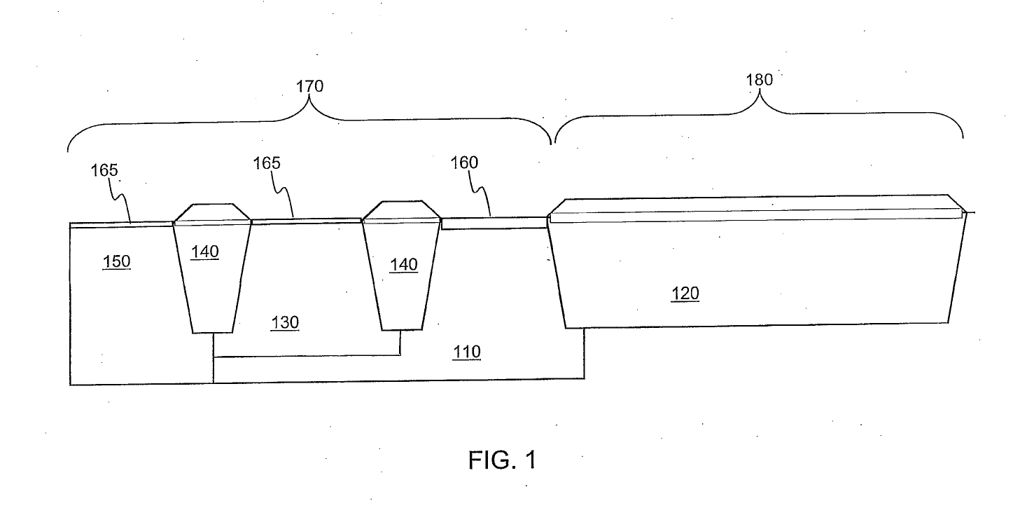

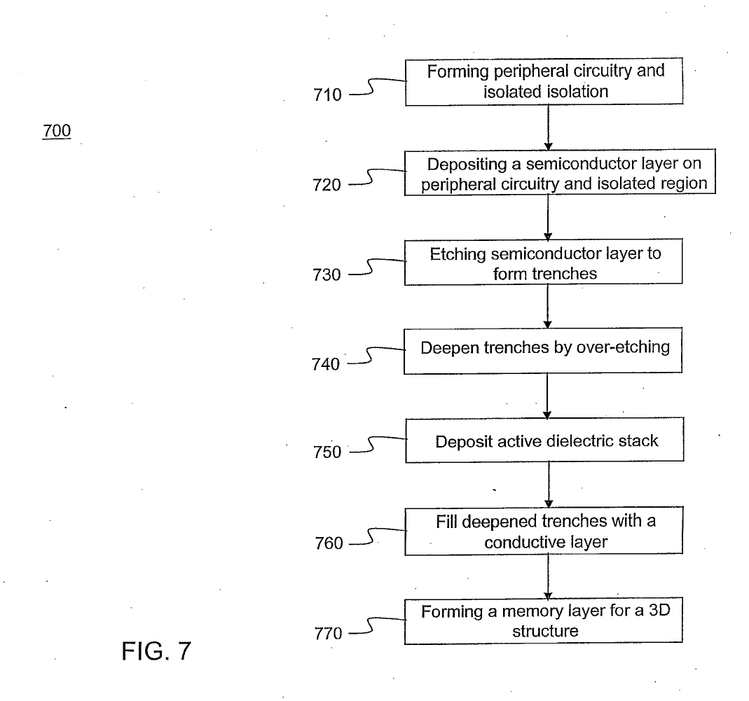

FIG. 7 is a flow diagram of a process 700 to form a memory device, according to a particular embodiment. Such a process will be described in conjunction with descriptions of FIGS. 1-5, which are cross-section views of portions of a memory device, according to an embodiment.

As shown in FIG. 1 and block 710 of process 700, a peripheral circuitry region 170 and an array region 180 may be formed in a semiconductor substrate. Well/threshold implantations, an active oxide, and/or an isolated (e.g., STI) region 120 may be formed. In particular, such implantation may result in a p-well region 110, a p-well region 130, an n-well region 150, and intervening field oxide regions 140, for example. A low voltage (LV) oxide 165 and a high voltage (HV) oxide 160 may be formed on well regions. STI region 120 may be defined using an oxide filling and subsequent chemical-mechanical polish (CMP), though claimed subject matter is not limited to such a definition technique.

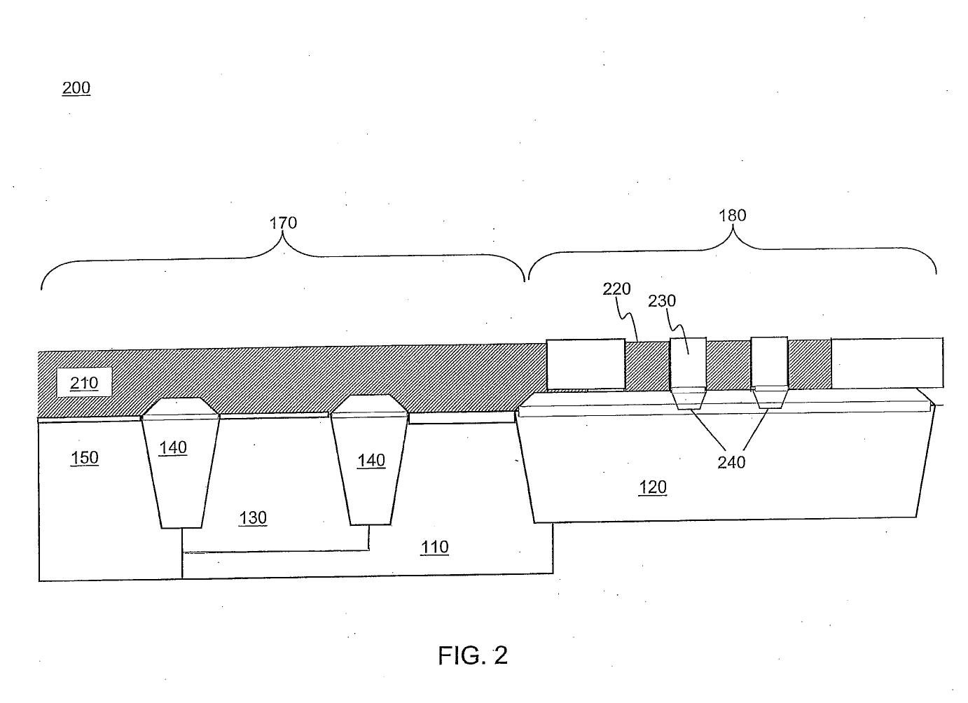

FIG. 2 is a cross-section view of a portion of a memory device 200, according to an embodiment. At block 720, a relatively thin semiconductor layer 210 may be deposited to at least partially cover peripheral circuitry region 170 and array region 180. Semiconductor layer 210 may comprise undoped semiconductor or semiconductor having relatively low doping. Semiconductor layer 210 may be used to seal circuitry and may comprise a bottom layer of a transistor gate, for example. In array region 180, semiconductor layer 210 may be selectively etched (e.g., via a masking process) to define cell channel regions 220. In particular, at block 730, semiconductor layer 210 may be etched over STI region 120 in order to expose portions of STI region 120 at the bottom of trenches 230. In a particular implementation, at block 740, such an etch process may comprise an over-etch process, wherein semiconductor layer 210 may be etched downward to a surface of STI region 120 and beyond, so that a portion 240 of STI region 120 is also etched. Accordingly, an additional etch depth resulting from such an over-etch process may provide trenches 230 with trench bottoms that are below a surface of STI region 120.

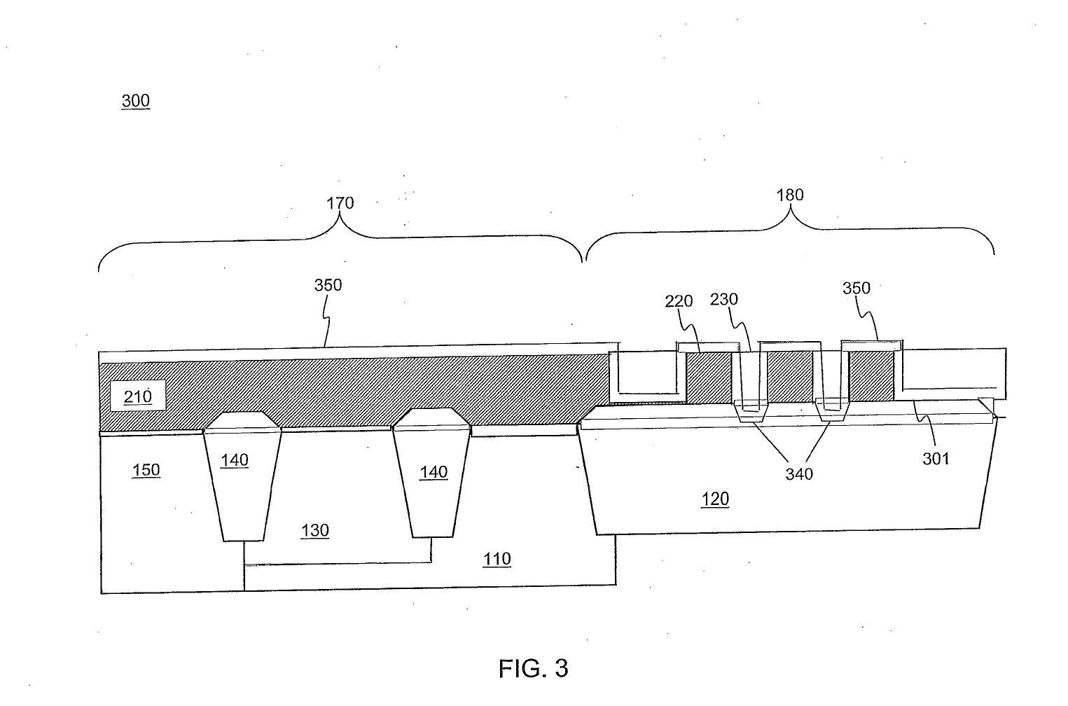

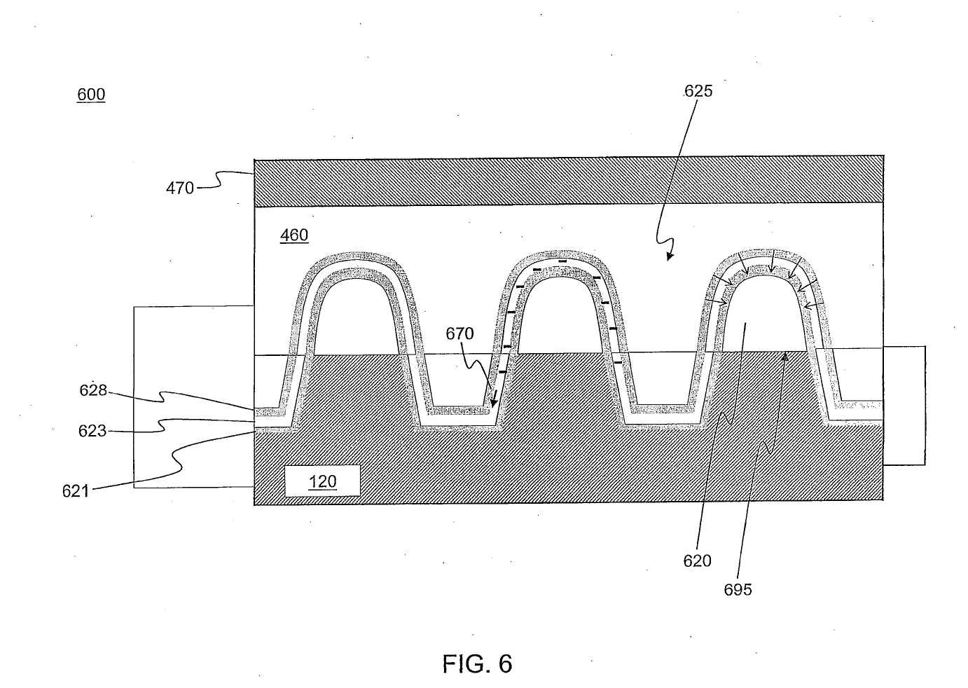

FIG. 3 is a cross-section view of a portion of a memory device 300, according to an embodiment. At block 750, charge trap active dielectric layers 350 may be deposited on semiconductor layer 210. In a particular implementation, such dielectric layers may comprise an active dielectric stack conformally deposited onto semiconductor layer 210. For example, such an active dielectric stack may comprise a tunnel oxide 621 (e.g., silicon oxide), a trapping dielectric layer 623 (e.g., silicon nitride), and a blocking dielectric layer 628 (e.g., silicon oxide), as shown in FIG. 6, for example, though claimed subject matter is not so limited.

Corresponding to lower portions of trenches 230 that are below a surface 301 of STI region 120, portions 340 of dielectric layers 350 may reside below surface 301 of STI region 120. Array region 180 may thus comprise a resulting structure that includes semiconductor lines covered by an active dielectric stack that define channel regions 220 separated by trenches 230 that extend below the channel regions 220. Accordingly, at least a portion of an underlying STI region 120 is etched at bottoms of trenches 230. Of course, such details of materials and configuration of a memory device are merely examples, and claimed subject matter is not so limited.

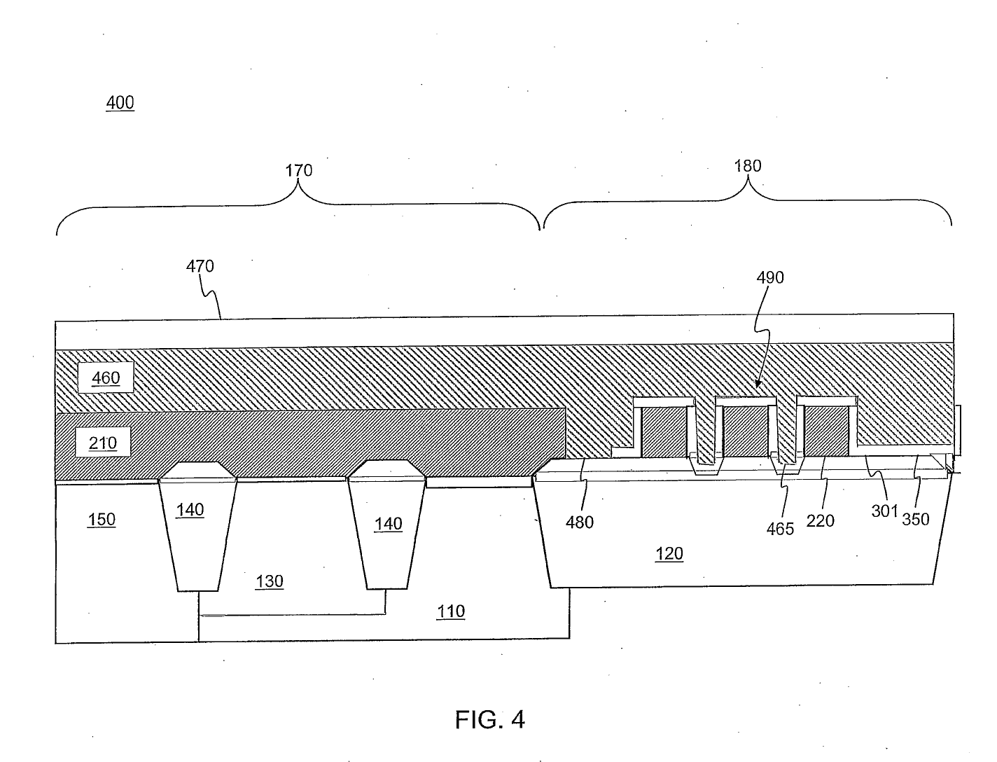

FIG. 4 is a cross-section view of a portion of a memory device 400, according to an embodiment. A second conductive layer 460 may be deposited on a portion of memory device 400 to at least partially cover peripheral circuitry region 170 and array region 180. Such a conductive layer 460 may comprise, for example, polysilicon, titanium, titanium nitride, tantalum nitride (TaN), tungsten (W), tungsten nitride (WN), tungsten silicide (WSi2), and/or a combination thereof. Of course, such materials are merely examples, and claimed subject matter is not so limited. In addition, at block 760, conductive layer 460 may at least partially fill trenches 230 between channel regions 220. Accordingly, at least portions 465 of conductive layer 460 may reside below a surface 301 of STI region 120. In other words, portions 465 of conductive layer 460 may extend below channel regions 220. In one implementation, a portion 480 of dielectric layers 350 may be removed between peripheral circuitry region 170 and array region 180 in order to electrically short conductive layer 460 with a low resistance metal layer 470.

A low resistance metal layer 470 may be deposited to at least partially cover conductive layer 460, including resulting memory cells 490. Such a metal layer may comprise, for example, titanium, titanium nitride, tungsten (W), tungsten nitride (WN), tungsten silicide (WSi2), and/or a combination thereof. Of course, such materials are merely examples, and claimed subject matter is not so limited. Such a low resistance metal layer 470 may provide a lowering of resistivity values of the array gate 180 and circuitry gates (not shown). In a particular implementation, though not shown, an interlayer dielectric layer (ILD), which may comprise an oxide for example, may be conformally deposited onto low resistance metal layer 470. An additional conformal nitride layer (not shown) may cover such an ILD and consequently form a foundation for which to fabricate a subsequent memory array level (not shown) to fabricate a three-dimensional memory structure, as at block 770.

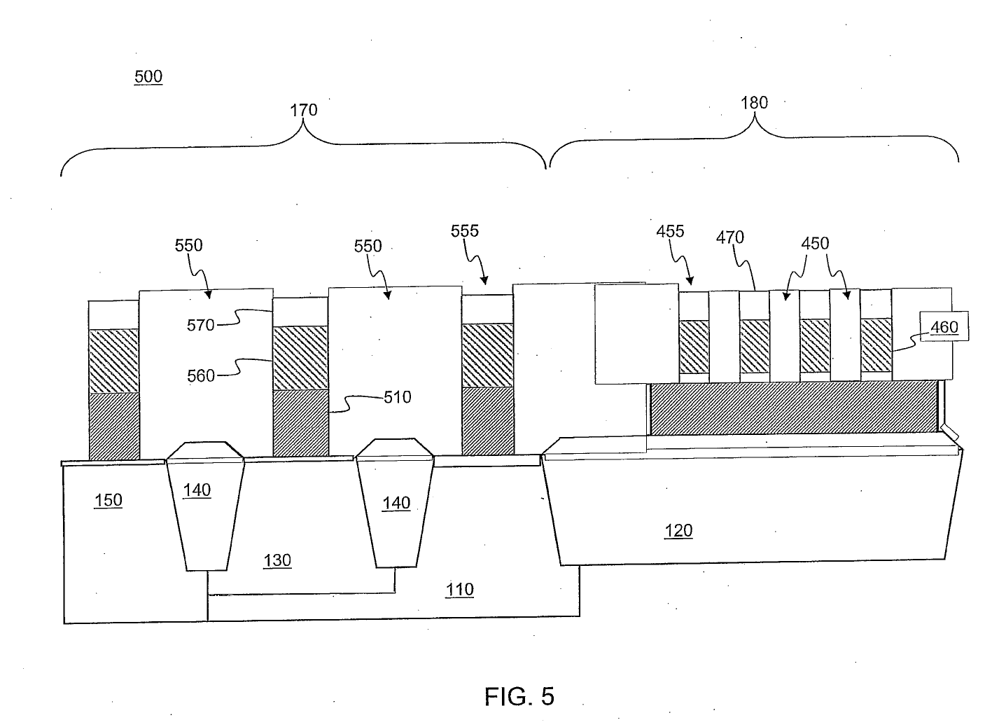

FIG. 5 is a cross-section view of a portion of a memory device 500, according to an embodiment. Transistor gate and/or array gates 555 and 455 may be defined by an etch process that forms trenches 550 and/or 450 in patterned semiconductor layer 510 (e.g., for circuitry), patterned conductive layer 560 and 460, and patterned low resistance metal layer 570 and 470.

FIG. 6 is a cross-section view of a portion of a memory array 600, according to an embodiment. As described above, semiconductor lines comprising cell channels 620 are formed on STI region 120. Cell channels 620 may be conformally covered with an active dielectric stack comprising a tunnel oxide layer 621, a trapping dielectric layer 623, and a blocking dielectric layer 628, for example, though claimed subject matter is not so limited. Trenches 625 separating resulting cell channels 620 may be at least partially filled with a conductive layer 460. Portions of the active dielectric stack and/or conductive layer 460 may reside below cell channels 620, e.g., below an interface 695 between cell channels 620 and STI region 120. Such a configuration may result in an increased path length for charged particles 670 diffusing from one cell channel 620 to an adjacent cell channel 620, compared to a configuration where active dielectric stack and/or semiconductor layer do not reside below cell channels 620. Thus, such an increased path length may provide a benefit such as improved memory retention by reducing a leakage current from one memory cell to an adjacent memory cell. Such a configuration may provide a benefit such as improved channel control during operation of memory cells, and/or increased tunnel electric field. Of course, such details of a memory array are merely examples of materials and configuration, and claimed subject matter is not so limited.

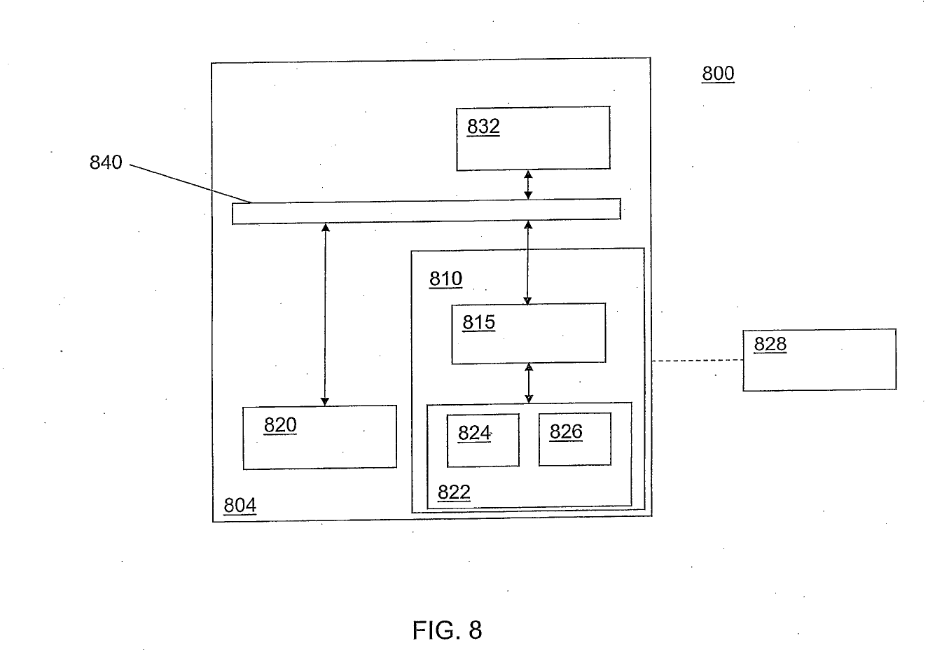

FIG. 8 is a schematic view of a computing system and a memory device, according to an embodiment. Such a computing device may comprise one or more processors, for example, to execute an application and/or other code. Memory device 810 may comprise a memory device, such as memory device 500 shown in FIG. 5 for example, which may be fabricated using one or more techniques described herein. A computing device 804 may be representative of any device, appliance, or machine that may be configurable to manage memory device 810. Memory device 810 may include a memory controller 815 and a memory 822. By way of example but not limitation, computing device 804 may include: one or more computing devices and/or platforms, such as, e.g., a desktop computer, a laptop computer, a workstation, a server device, or the like; one or more personal computing or communication devices or appliances, such as, e.g., a personal digital assistant, mobile communication device, or the like; a computing system and/or associated service provider capability, such as, e.g., a database or data storage service provider/system; and/or any combination thereof.

It is recognized that all or part of the various devices shown in system 800 may be implemented using or otherwise including hardware, firmware, software, or any combination thereof. Thus, by way of example but not limitation, computing device 804 may include at least one processing unit 820 that is operatively coupled to memory 822 through a bus 840 and a host or memory controller 815. Processing unit 820 is representative of one or more circuits configurable to perform at least a portion of a data computing procedure or process. By way of example but not limitation, processing unit 820 may include one or more processors, controllers, microprocessors, microcontrollers, application specific integrated circuits, digital signal processors, programmable logic devices, field programmable gate arrays, and the like, or any combination thereof. Processing unit 820 may include an operating system configured to communicate with memory controller 815. Such an operating system may, for example, generate commands to be sent to memory controller 815 over bus 840. Such commands may comprise read and/or write commands. In response to a write command, for example, memory controller 815 may provide a bias signal, such as a set or reset pulse to write information associated with the write command to a memory partition, for example. In an implementation, A system 800 may comprise a memory device 810 including an array of charge trap memory cells comprising an STI region on a substrate, semiconductor lines formed on the STI region, an active dielectric stack conformally covering the semiconductor lines, and a conductive layer at least partially covering the active dielectric stack. In such a case, at least portions of the conductive layer may extend to substantially below the semiconductor lines. Memory controller 815 may operate memory device 810, wherein processing unit 820 may host one or more applications and/or initiate write commands to the memory controller to provide access to memory cells in memory device 810, for example.

Memory 822 is representative of any data storage mechanism. Memory 822 may include, for example, a primary memory 824 and/or a secondary memory 826. Primary memory 824 may include, for example, a random access memory, read only memory, etc. While illustrated in this example as being separate from processing unit 820, it should be understood that all or part of primary memory 824 may be provided within or otherwise co-located/coupled with processing unit 820.

Secondary memory 826 may include, for example, the same or similar type of memory as primary memory and/or one or more data storage devices or systems, such as, for example, a disk drive, an optical disc drive, a tape drive, a solid state memory drive, etc. In certain implementations, secondary memory 826 may be operatively receptive of, or otherwise configurable to couple to, a computer-readable medium 828. Computer-readable medium 828 may include, for example, any medium that can carry and/or make accessible data, code, and/or instructions for one or more of the devices in system 800.

Computing device 804 may include, for example, an input/output 832. Input/output 832 is representative of one or more devices or features that may be configurable to accept or otherwise introduce human and/or machine inputs, and/or one or more devices or features that may be configurable to deliver or otherwise provide for human and/or machine outputs. By way of example but not limitation, input/output device 832 may include an operatively configured display, speaker, keyboard, mouse, trackball, touch screen, data port, etc.

While there has been illustrated and described what are presently considered to be example embodiments, it will be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular embodiments disclosed, but that such claimed subject matter may also include all embodiments falling within the scope of the appended claims, and equivalents thereof.

1. A method of fabricating a memory device, the method comprising:
etching a first semiconductor layer that is at least partially covering peripheral circuitry and an isolated region on a substrate to form trenches to expose said isolated region; and
etching said isolated region at the bottom of said trenches to deepen said trenches to substantially below said first semiconductor layer.

2. The method of claim 1, further comprising:
conformally forming an active dielectric stack on said etched first semiconductor layer and surfaces of said deepened trenches to substantially below said first semiconductor layer.

3. The method of claim 2, further comprising:
at least partially filling said deepened trenches to substantially below said first semiconductor layer with a second conductive layer to form an array of memory cells.

4. The method of claim 1, further comprising:
forming a memory array layer on said isolated region, wherein said memory device comprises a three-dimensional memory device.

5. The method of claim 1, wherein said etching said first semiconductor layer over said isolated region further comprises:
patterning said first semiconductor layer to form substantially parallel multiple semiconductor lines.

6. The method of claim 3, wherein said first semiconductor layer comprises channel regions of said memory cells.

7. The method of claim 3, wherein said second conductive layer comprises source lines and/or gate lines of said memory cells.

8. The method of claim 1, wherein said array of memory cells comprises a charge trap NAND memory cell array.

9. A memory device comprising:
an array of charge trap memory cells comprising:
an active dielectric stack conformally covering semiconductor lines formed on an isolated region on a substrate; and
a conductive layer at least partially covering said active dielectric stack, wherein at least portions of said conductive layer extend to substantially below said semiconductor lines.

10. The memory device of claim 9, wherein at least portions of said active dielectric stack extend to substantially below said semiconductor lines.

11. The memory device of claim 9, further comprising:
one or more memory array layers on said isolated region, wherein said memory device comprises a three-dimensional memory device.

12. The memory device of claim 9, wherein said semiconductor lines comprise channel regions of said charge trap memory cells.

13. The memory device of claim 9, wherein said conductive layer comprises source lines and/or gate lines of said charge trap memory cells.

14. The memory device of claim 9, wherein said array of charge trap memory cells comprises a charge trap NAND memory cell array.

15. A system comprising:
a memory device comprising:
an array of charge trap memory cells comprising
an active dielectric stack conformally covering semiconductor lines formed on an isolated region on a substrate, and
a conductive layer at least partially covering said active dielectric stack, wherein at least portions of said conductive layer extend to substantially below said semiconductor lines; and
a memory controller to operate said memory device, said
a processor to host one or more applications and to initiate write commands to said memory controller to provide access to memory cells in said memory arrays.

16. The system of claim 15, wherein at least portions of said active dielectric stack extend into said isolated region.

17. The system of claim 15, wherein said system further comprises:
one or more memory array layers on said substrate, wherein said memory device comprises a three-dimensional memory device.

18. The system of claim 15, wherein said semiconductor lines comprise channel regions of said charge trap memory cells.

19. The system of claim 15, wherein said conductive layer comprises source lines and/or gate lines of said charge trap memory cells.

20. The system of claim 15, wherein said charge trap memory cells comprise charge trap NAND memory cells.

21. The memory device of claim 9, wherein said active dielectric stack comprises a double silicon dioxide layer including a silicon nitride layer to be used as a storage layer.

22. The memory device of claim 9, wherein said active dielectric stack comprises an oxide-nitride-oxide (ONO) stack.

23. The memory device of claim 9, wherein at least portions of said active dielectric stack extend to below said semiconductor lines by a distance greater than a thickness of said active dielectric stack.

24. The memory device of claim 9, wherein the memory device is incorporated in at least one of the following: a desktop computer, a laptop computer, a workstation, a server device, a personal digital assistant, a mobile communication device, or any combination thereof.
